(19) United States
(12) Patent Application Publication
(10) Pub. No.: US 2025/0368072 A1
(43) Pub. Date: Dec. 4, 2025

(54) CHARGING STATION

(71) Applicant: JOYSONQUIN Automotive Systems GmbH, Rutesheim (DE)

(72) Inventor: Stefan BROMMER, Tamm (DE)

(21) Appl. No.: 18/870,675

(22) PCT Filed: Sep. 25, 2023
(86) PCT No.: PCT/EP2023/076352

§ 371 Date: Dec. 1, 2024

(30) Foreign Application Priority Data
Oct. 4, 2022 (DE) 20 2022 105 609.9

(51) Int. Cl. B60L 53/302; B60L 53/16; B60L 53/18; H05K 7/20

(52) U.S. Cl. CPC B60L 53/302; B60L 53/16; B60L 53/18; H05K 7/20127; H05K 7/20136; H05K 7/20209; H05K 7/20336

(57) ABSTRACT

The present invention relates to a charging station (2) for charging an electric vehicle, in particular a wallbox, the charging station (2) comprising a housing (10), an electronic system (20) arranged in the housing (10) for controlling a charging current, a temperature control device (30) to be connected or connected to the electronic system (20) in a heat-conducting manner for controlling the temperature of the electronic system (20), wherein the temperature control device (30) has a heat emitting pipe (32) with a fluid heat carrier (W), characterized in that the heat emitting pipe (32) is guided out of the housing (10) via at least one penetration (12) of the housing (10) which is to be sealed or is sealed.

The present invention relates to a charging station for charging an electric vehicle, wherein the charging station comprises an electronic system for controlling a charging current, and wherein the charging station comprises a temperature control device for controlling the temperature of the electronic system.

Such charging stations are also referred to as “wallbox”, even if they are not attached to a wall.

The electric vehicle can be one that is capable of fully electric locomotion, at least for a short time. The electric vehicle has a battery that can be charged using the charging station.

Electromobility requires a network of charging stations (EV charging facilities) for the battery that is as comprehensive as possible. This is currently being structured. In Germany in particular, so-called alternating current or AC wallboxes are being used. These provide the vehicle with an alternating voltage via a simple contactor or relay circuit, which typically still needs to be rectified. The AC wallboxes can also protect the operator (e.g. by detecting residual currents) and ensure that the existing power supply circuit is not overloaded by means of integrated or connected components.

In most cases, AC wallboxes are limited to 22 kW charging power due to various restrictions. It is often not possible to install more than 22 kW charging power in private or domestic environments.

As already mentioned, the alternating current flowing through the battery must typically be rectified for the charging process. This is done, for example, in an assembly called an onboard charger (OBC), which has a rectifier and is installed in the electric vehicle. For technical and economic reasons, the OBC is often not adapted to high charging capacities. The OBC may even be adapted for less than 22 kW charging power.

In principle, the electric vehicle can also be supplied with direct current/direct voltage (DC) instead of alternating current/alternating voltage. Since no rectification is necessary when the electric vehicle is supplied with a DC voltage in the vehicle, no OBC is required. This means that the OBC can be dispensed with as a factor limiting the charging power and higher charging powers can also be supplied to the battery, for example more than 22 kW.

It can therefore be assumed that, in addition to fast chargers in the public sector using DC voltage, a DC wallbox will also become increasingly popular in private homes.

A wallbox or charging station is mainly supplied with alternating voltage (AC). In this respect, the rectification of the AC voltage into a DC voltage can be carried out by the electronic system in the charging station, which ultimately also falls under the control of the charging current. This conversion, thus rectification, is not completely loss-free. Conversion losses occur, which can be in the range of a few percent of the charging power and represent a power loss. The power loss is present in the form of waste heat.

For example, a 22 kW charging station with a theoretical efficiency of 0.99 can theoretically generate up to 220 W of power loss in the form of waste heat, which must be dissipated from the area around the electronic system. In practice, higher values can be assumed.

The waste heat can be dissipated using the aforementioned temperature control device, for example by means of cooling elements and/or a fan. The better the waste heat is dissipated, the lower the available temperature at the electronic system. This temperature must be kept low in order to prevent the electronic components of the system from ageing too quickly. Larger cooling elements and/or fans can be used to improve the removal of waste heat and thus lower the temperature of the electronic system. However, this also means that the charging station has to become larger to better dissipate the waste heat, which makes it more expensive to manufacture and sell and ultimately less attractive at the installation site. In addition, it is generally necessary to provide a fail-safe and fire-protected charging station with a temperature control system.

CN 2 17 415 520 U, CN 2 11 745 104 U and CN 1 14 701379 A each disclose a charging station with a housing, an electronic system arranged therein, and a temperature control device connected to the electronic system in a heat-conducting manner. The temperature control device has a heat emitting pipe with a fluid heat carrier. The housing completely accommodates the heat emitting pipe and is equipped with at least one fan. The fan ensures that the heat emitting pipe is exposed to forced convection via an air flow through the housing, so that waste heat from the electronic system is transported out of the housing.

CN 2 14 775 425 U discloses a charging station with a housing forming two chambers, an electronic system arranged in a first chamber, and a heat-conducting temperature control device connected to the electronic system and leading to the second chamber. The temperature control device has a heat emitting pipe with a fluid heat carrier. Furthermore, fans are provided in the second chamber on the heat emitting pipe, which ensure an exchange of air in the housing or in the second chamber, so that waste heat from the electronic system arranged in the first chamber is finally transported out of the second chamber via slots in the housing.

CN 1 13 865 391 A discloses a charging station with a housing, an electronic system arranged therein and a heat-conducting temperature control device connected to the electronic system. The temperature control device has a heat emitting pipe with a fluid heat carrier. The heat emitting pipe is guided predominantly in the housing and predominantly vertically. Waste heat can be dissipated via outside air via horizontal outer sections of the heat emitting pipe, which are equipped with ribs.

The present invention is based on the problem of improving the charging station in such a way that waste heat from the electronic system can be dissipated in a space-saving and fail-safe manner. In addition, a use is to be indicated with which existing charging stations can also be improved.

In order to solve this problem, the present invention provides a charging station with the features of claim 1. In addition, the features of the further claims are proposed as further solutions to the problem.

A charging station for charging an electric vehicle with a housing is proposed. The charging station has an electronic system arranged or to be arranged in the housing for controlling a charging current. The charging station also has a temperature control device to be connected or connected to the electronic system in a heat-conducting manner for controlling the temperature at the electronic system. The temperature control device has a heat emitting pipe with a fluid heat carrier.

As proposed, the heat emitting pipe is guided out of the housing via at least one sealed penetration in the housing. This prevents water from entering the housing and increases fail-safe operation.

The heat emitting pipe is a known object in the field of heating technology. In particular, the heat emitting pipe proposed here has an elongated, possibly curved or bent metallic vessel, at least in sections, in which a volume containing the heat carrier is hermetically encapsulated. In particular, the vessel has an evaporator area for absorbing heat by evaporating the heat carrier in the volume and a condenser area spaced apart from the evaporator area for dissipating heat by condensing the heat carrier in the volume. The evaporator area is provided in particular for arrangement in the vicinity of or on the electronic system. In particular, the condenser area is to be arranged spaced apart from it in order to dissipate the absorbed waste heat elsewhere.

This preferably results in that the waste heat from the electronic system does not or at least no longer significantly needs to be dissipated from the housing as an air flow directly at the electronic system. The waste heat can now preferably be transported through the heat emitting pipe to a location at a distance from the electronic system, where it can be dissipated into the environment. In this way, the housing can be adapted to be slimmer or less oriented towards dissipating the waste heat from the electronic system.

Due to the heat emitting pipe, the temperature control device can be adapted more flexibly to the housing. Thanks to the heat emitting pipe, the housing can be configured in a very space-saving manner, in particular because the waste heat can be dissipated by the heat emitting pipe with condensation of the heat carrier at a greater distance from the electronic system and therefore at a lower ambient temperature.

It is particularly preferable for the temperature control device to be configured such that the heat carrier transports or dissipates the waste heat at least essentially or exclusively by natural convection. For this purpose, the heat emitting pipe should be arranged vertically, at least in sections or predominantly, preferably completely. It may be provided that the temperature control device can be operated free of forced convection, in particular with regard to the heat carrier and/or with regard to the dissipation of the waste heat away from the heat emitting pipe. It may be provided that the temperature control device does not have a working machine for a fluid, such as a fan or a pump. In particular, it is provided that the waste heat is released from the temperature control device to the environment at least essentially or exclusively by natural convection.

The charging station under consideration here is preferably a wallbox. In particular, the charging station is configured or provided for wall mounting. In the case of wall mounting, the charging station is at a distance from the ground or floor. Preferably, the charging station has a mounting option for wall mounting, for example mounting holes in the housing, in particular for screwing the charging station to a facade or wall, in particular at a distance from the ground. Preferably, the charging station is configured without a base for installation. However, it is not excluded that the charging station can be arranged or set up with a stand.

If the heat emitting pipe has a heat pipe and/or a two-phase thermosiphon, particularly effective removal of the waste heat is possible. In particular, the heat pipe has a capillary structure. In particular, the two-phase thermosiphon does not have a capillary structure. The capillary structure is usually provided or not provided inside the heat emitting pipe in order to interact with the fluid heat carrier and transport it to the place of evaporation. The capillary structure can ensure that the partly fluid heat carrier is transported by capillary action. This is useful if the heat emitting pipe runs unfavorably for the flow of a fluid, for example horizontally.

The heat carrier may comprise water or at least one other substance that can undergo a phase transition between at least two of solid, liquid and gas. The other substance or substances may, for example, comprise at least one hydrocarbon compound and/or ammonia. In particular, the heat carrier should be able to undergo a phase transition in the temperature range between 0 and 100° C. in order to be able to carry out the heat of fusion or heat of vaporization for heat removal from the electronic system under typical conditions. Depending on the filling quantity of the heat carrier in the heat emitting pipe, a pressure can be set in the heat emitting pipe and the temperature of a phase transition can be influenced in this respect. Water as a heat carrier is non-toxic and, depending on the filling quantity in the heat emitting pipe, is well suited for various operating temperatures. Other heat carriers may be able to transport heat/waste heat even better due to an increased or at least adapted enthalpy of vaporization compared to water.

Preferably, the temperature control system is adapted to dissipate a heat flow of up to or at least 250 W, 500 W or 1000 W from the electronic system at an ambient temperature of up to 60° C. In particular, it can be useful to adapt the temperature control device with regard to maximum performance so as not to oversize it. An adaption with regard to a minimum performance can be useful in order to be prepared for upgrades of the electronic system. The specified values in particular have proven to be suitable in the field of e-mobility, where power losses of this magnitude have to be dissipated in the form of waste heat, wherein this can be done easily using the heat emitting pipe.

The electronic system can have a control component that is configured in particular to control the charging current.

The control component can have a so-called power section or power electronics, preferably for rectifying the charging current and/or for regulating the charging current, in particular by emitting waste heat. Alternating rectification by means of the control components is of course also conceivable. For example, the power section can have a converter, in particular a frequency converter, a rectifier and/or an inverter. In particular, the control component or the power section has at least one of the following electronic structural elements: Diac, bipolar power transistor, power MOSFET, GTO thyristor, IGBT, thyristor, triac, diode for rectification and/or power capacitor.

The heat emitting pipe can be connected to the control component of the electronic system in a heat-conducting manner. The heat emitting pipe can be in surface contact with the control component or with a cooling element of the same in order to absorb the waste heat. The heat emitting pipe can be soldered, glued, clamped, screwed and/or inserted on the electronic system or on the cooling element. In particular, if the heat emitting pipe is fixed directly or indirectly in the area of the control component, the heat carrier can evaporate in the heat emitting pipe in a targeted manner and thus absorb the waste heat and transport it in the heat emitting pipe. A heat-conducting paste can be applied between the heat emitting pipe and the control component or the cooling element to further improve heat transfer.

Preferably, an outer section of the heat emitting pipe for heat exchange with the environment is arranged outside the housing. In this way, waste heat cannot only be effectively transported from the control component to another location in the housing, but also to the environment outside the housing without having to drive an air flow of a fan through the housing. The outer section can be arranged on the housing in a way that is adapted to the natural or forced convection of the outer section. For example, the outer section can be arranged in such a way that surface sections of the outer section are aligned vertically like cooling fins and are cooled by the ambient air via natural convection.

Preferably, the heat emitting pipe extends through a wall of the housing or housing wall. Preferably, the heat emitting pipe extends from the inside to the outside, in particular from the inside of the housing to the surroundings of the housing outside the housing. One/the outer section of the heat emitting pipe can be arranged outside the housing. In particular, an inner section of the heat emitting pipe is connected to the electronic system in a heat-conducting manner. The inner section is preferably arranged inside the housing.

Preferably, the heat emitting pipe is guided out of the housing via penetrations of the housing that are to be sealed or sealed—or at least one of such penetrations. The penetrations can be feedthroughs, for example sealing feedthroughs. In particular, the feedthrough is a feedthrough similar or identical in construction to a cable feedthrough. In particular, the feedthrough or cable feedthrough is adapted for a temperature range between 0° C. and 100° C. This ensures that the heat emitting pipe does not cause any weak points on the housing. In particular, moisture cannot penetrate the housing. The penetrations can be arranged at the bottom, side and/or top of the housing. A penetration can be formed by or have at least one bore or opening in the housing.

Preferably, the penetration has a sealing device, in particular a cable gland. In particular, the heat emitting pipe is guided out of the housing through the sealing device. In particular, the sealing device is arranged on the housing and/or on the heat emitting pipe, for example in contact with it, in particular attached to it.

This creates a good and permanently reliable seal and, at the same time, good accessibility to this seal in order to check or replace it. The heat emitting pipe can also be easily replaced or repaired if necessary.

The penetration can have an at least essentially annular sealing device, for example comprising or consisting of a seal configured in particular as a sleeve or sleeve seal. The sealing device can surround the heat emitting pipe, in particular in an annular shape. The sealing device can be at least partially flexible. The sealing device can have a connecting piece that can seal against the heat emitting pipe and the housing, for example by means of at least one seal. For example, the sealing device or seal can be arranged inside or outside the housing (or also on the inner and outer sides). The seal can be configured as a flat seal (flat and/or square in cross-section) or as a round seal (round in cross-section); a combination of flat and round seals is also conceivable. The sealing device can be inserted, attached, glued and/or screwed to the housing, in particular by means of a nut. For example, the sealing device for a seal may be made of plastic, silicone and/or rubber, or the seal may consist of these materials. The sealing device can abut the heat emitting pipe and/or the housing. For example, the sealing device can guide the heat emitting pipe relative to the housing. The sealing device can hold and/or seal the heat emitting pipe. In particular, the sealing device is arranged and/or inserted in or on an opening and/or bore of the housing. The sealing device or the penetration can alternatively or additionally be formed on the housing and/or be a section of the housing.

The penetration can have a cable gland or be formed by a cable gland. The cable gland can also be part of or form the sealing device. A cable gland is a form of cable feedthrough or cable entry, thus a feedthrough or entry formed for a cable. Cable glands use a sealing element or sealing insert to ensure that a fed-through cable can be fed through tightly. The idea is that the heat emitting pipe is arranged in the cable gland instead of a cable. This is because it has been found that the heat emitting pipe can also be fed through tightly by means of a cable gland, and not only cables with the cable gland can be used. It is particularly preferable for the heat emitting pipe to be guided out of the housing in an atmosphere-tight manner. A protection class can be provided for the cable gland, see German standard DIN EN 60529, in particular VDE 0470-1:2014-09. Protection class IP66 is preferred. In particular, the heat emitting pipe is particularly well mechanically fixed by means of a cable gland and thus well secured even in the event of impacts against the charging station.

In particular, the penetration therefore has a cable gland. The cable gland can be attached to the housing. The heat emitting pipe is preferably guided out of the housing through the cable gland, in particular in an atmosphere-tight manner.

Atmosphere-tight means, for example, airtight and/or watertight, for example splash-proof, for example in such a way that even when watering directly with a jet of water with heavy rain or a jet from a high-pressure cleaner, at least substantially or no water at all can penetrate. The protection class IP66 is understood to mean atmosphere-tight sealing.

The outer section is in particular located predominantly or exclusively outside the housing. This creates a particularly environmentally protected charging station. In particular, no water can reach the electronic system via the penetration, even in heavy rain, and at the same time the waste heat is dissipated very effectively. In particular, there is no need for fans, air vents or the like, which would otherwise provide access for water into the housing.

A cable gland typically comprises a sleeve-shaped or tubular insertion part that can be inserted into an opening in a wall or housing and has at least a first threaded section and optionally a second threaded section. A union nut can be screwed or is to be screwed onto the insertion part, in particular when the cable or heat emitting pipe is fed through. The union nut regularly has an internal thread for the first threaded section and an internal cone for interacting with a cage of the insertion part.

A cage and in particular a sealing element can be provided on the insertion part, in particular adjacent to the first threaded section. In particular, the sealing element is arranged in the cage. The union nut can use a cone to radially compress the cage and/or the sealing element when it is screwed on, for example to seal the insertion part against the heat emitting pipe. The cage is formed in particular from a plurality of axially aligned webs or fingers, which are arranged at a free end for the union nut. A radial projection or shoulder can be provided adjacent to the first threaded section, which can abut when inserted into the wall or housing.

Furthermore, a further nut can be arranged on the first and/or second threaded section, which is preferably provided as a lock nut that can be pressed against the wall or the housing, in particular in interaction with the union nut and/or a/the radial projection of the insertion part. The insertion part can be configured to seal against the wall or the housing. At least one seal or at least one sealing ring or two or more of these can be provided on the insertion part, which is/are provided for contact with the wall or the housing and the nut and/or the union nut. A seal or sealing ring can be provided on an axial side, in particular away from or opposite the union nut, e.g. on the nut. A seal or sealing ring can be provided on the first or second threaded section.

Finally, in preferred configurations it is provided that the penetration has a cable gland with an insertion part and that the heat emitting pipe is guided out of the housing via the cable gland and through the insertion part inserted into the housing.

In addition, it may be provided that the insertion part is sealed against the housing by at least one seal, in particular a sealing ring, of the cable gland.

The insertion part can be sealed against the heat emitting pipe via at least one sealing element of the cable gland accommodated in the insertion part, in particular where the sealing element is accommodated in a cage formed from axially extending fingers.

It is also possible that the insertion part is attached to the housing by means of a nut of the cable gland screwed onto the insertion part, wherein in particular the nut is screwed against the at least one seal or a sealing ring.

Alternatively or additionally, the heat emitting pipe can be clamped to the cable gland by means of a union nut of the cable gland screwed onto the insertion part, wherein in particular the union nut surrounds the sealing element and clamps it against the heat emitting pipe.

If the outer section has cooling surfaces and/or a cooling element, the waste heat absorbed in the housing can be dissipated even better to the environment. The cooling surfaces or the cooling element can be a body fixed to the heat emitting pipe with elongated or flat sections made of copper and/or aluminum or alloys thereof. In particular, the cooling surfaces must be at least partially and/or predominantly aligned vertically in order to achieve natural convection.

Preferably, the outer section is arranged on the housing so that it is protected against impact. This can be realized by enclosing and/or surrounding the outer section at least in sections by projections of the housing. This ensures that the outer section is not inadvertently deformed or damaged.

If the heat emitting pipe is arranged at least in sections non-horizontally and/or at least in sections at least essentially vertically, good waste heat removal is ensured, as the return flow of condensed heat carrier back to the source of the waste heat usually only works satisfactorily if the heat emitting pipe is arranged at an angle. A non-horizontal arrangement is one that is inclined by at least 5° relative to the horizontal.

At least essentially vertical is an arrangement that is inclined by at least 45° from the horizontal, preferably at least 60°, more preferably at least 70° or 80°, particularly preferably 85° or 90°±2°.

If the temperature control device has a fan that can be activated depending on the temperature, the safety of the charging station is increased. This is because the removal of waste heat via the heat emitting pipe may not be sufficient to keep the temperature at the control component at a sufficiently low level. In this case, the fan can be started depending on a measured or thermostatically determined temperature, so that the waste heat can be dissipated more effectively from the heat emitting pipe and/or in the housing.

Preferably, a charging cable electrically connected to the electronic system is provided, wherein the charging cable has a charging plug at a free end for connection to the electric vehicle. In this way, a charging station can be provided that is already fully operational and is improved by the heat emitting pipe compared to the known charging stations.

Finally, as a further solution, a use of a temperature control device for controlling the temperature of an electronic system of a charging station is proposed, wherein the charging station is configured as described above, in particular comprises a/the heat emitting pipe. In particular, a use with the features of claim 17 is proposed.

It is also proposed that the charging station is configured as a wallbox for wall mounting. Likewise, a use of the charging station described here as a wallbox for wall mounting is proposed. In other words, it is proposed that the charging station be configured or provided as a wallbox and/or mounted on a wall, in particular without a base.

Further details and advantages of the present invention are shown in the following description of an embodiment in conjunction with the drawing. Therein:

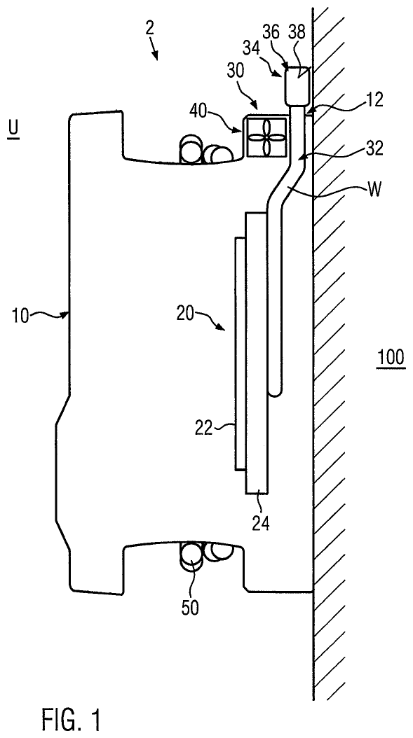

FIG. 1 shows a cross-sectional view of a first embodiment of a charging station according to the invention with a temperature control device comprising a heat emitting pipe, and

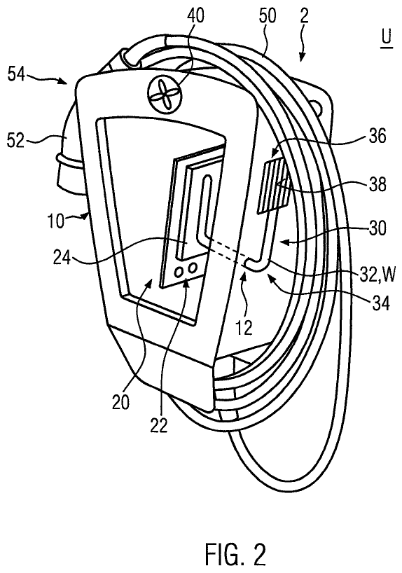

FIG. 2 shows a perspective view of a second embodiment of a charging station according to the invention with a temperature control device comprising a heat emitting pipe.

FIG. 1 shows a charging station 2 in a cross-sectional view. The charging station 2 is suitable for charging an electric vehicle (not shown) and has a housing 10. An electronic system 20 for controlling a charging current is arranged in the housing 10, wherein the electronic system is configured for rectifying alternating current.

The charging station 2 is attached to a wall 100. The wall 100 can provide an AC voltage for the charging station 2, which can then be rectified in the charging station 2. The charging station 2 is configured as a wallbox.

A temperature control device 30 is connected to the electronic system 20 and is provided for controlling the temperature of the system 20. The temperature control device 30 has a heat emitting pipe 32 with a fluid heat carrier W contained therein. The heat emitting pipe 32 is a two-phase thermosiphon, wherein the heat emitting pipe 32 is filled with water as the heat carrier W. The water is present in a liquid and gaseous state when the heat emitting pipe 32 is at room temperature.

The temperature control device 30 is adapted to dissipate a heat flow or waste heat of 500 W at an ambient temperature of up to 60° C. from the electronic system 20.

The heat emitting pipe 32 is connected to a control component 22 of the electronic system 20 in a heat-conducting manner via a cooling element 24 of the electronic system 20.

The heat emitting pipe 32 is provided with heat-conducting paste on the cooling element 24 and screwed to it. The heat carrier W in the heat emitting pipe 32 can evaporate on the cooling element 24 if the electronic system 20 generates sufficient waste heat. The cooling element 24 is in heat-conducting contact with the electronic system 20 or the control component 22.

An outer section 34 of the heat emitting pipe 32 guided out of the housing 10 is arranged outside and above the housing 10 for heat exchange with the environment U.

The heat emitting pipe 32 is guided out of the housing 10 via a sealed penetration 12 of the housing 10. The penetration 12 is arranged at the top of the housing 10.

In particular, the heat emitting pipe 32 is guided out of the housing 10 at the top, thus at an upper side of the housing 10. In particular, the heat emitting pipe 32 is aligned predominantly vertically. In this way, the heat emitting pipe 32 is utilized particularly effectively and, with regard to the heat carrier W, good use is made of the natural convection within the heat emitting pipe 32.

The penetration 12 has a sealing device, more precisely a cable gland. The heat emitting pipe 32 is guided out of the housing 10 in an atmosphere-tight manner via the penetration 12. The cable gland is plugged into the housing 10 in a sealing manner, for example by means of a sealing ring or seal, typically screwed on with a nut. The heat emitting pipe 32 is clamped in the cable gland with a union nut of the cable gland in a sealing manner. A sealing element abuts the heat emitting pipe 32 and is compressed by the union nut in order to seal directly against the heat emitting pipe 32. In the present case, the cable gland is predominantly or essentially enclosed in the housing 10 and is therefore not visible in the Figures.

The outer section 34 has cooling surfaces 36 on a cooling element 38. Here, the waste heat from the electronic system 20 can be dissipated to the environment U by convection, thus typically by natural convection. It is also conceivable that a fan is arranged on the outer section 34 in order to be able to dissipate even more waste heat in case of doubt than is possible with a purely passive arrangement or with only natural convection.

The outer section 34 is arranged on the housing 10 in an impact-protected manner in that the outer section 34 is located on top of or above the housing 10. This means that lateral contact with the charging station 2 cannot cause any damage to the outer section 34.

The heat emitting pipe 32 is arranged non-horizontally. More precisely, the heat emitting pipe runs essentially vertically.

The temperature control device 30 has a fan 40 that can be activated depending on the temperature.

The charging station 2 of FIG. 1 also has a charging cable 50 electrically connected to the electronic system 20, which is wound around the housing 10.

It is not shown that the charging cable 50 has a charging plug 52 at a free end 54 for connection to the electric vehicle.

In the charging station 2 shown in FIG. 2, the heat emitting pipe 32 is used to control the temperature of the electronic system 20. Reference is made to the fact that an essential aspect of the present invention is that known charging stations 2 can be improved with a heat emitting pipe 32. In this respect, the use of the heat emitting pipe 32 in a charging station 2 is generally proposed.

FIG. 2 shows another embodiment of a charging station 2. For reasons of clarity, a front cover on the housing 10 is hidden so that an electronic system 20 in the housing 10 is visible.

The charging station 2 is suitable for charging an electric vehicle. The charging station 2 essentially corresponds to the charging station 2 of FIG. 1. However, the heat emitting pipe 32 of the temperature control device 30 is not guided out of the housing 10 at the top, but at the side via a penetration 12. In this respect, the heat emitting pipe 32 runs horizontally in sections. The heat emitting pipe 32 is furthermore configured here as a heat pipe, according to which a capillary structure in the horizontal section of the heat emitting pipe 32 ensures a return transport of the condensed or fluid heat carrier W from the outer section 34 back into the housing 10.

Cooling surfaces 36 of the cooling element 38 on the outer section 34 are arranged in a substantially vertical direction so that natural convection can take place.

The charging station 2 further has a charging cable 50 electrically connected to the electronic system 20, which has a charging plug 52 at a free end 54 for connection to the electric vehicle.

The charging cable 50 is wound or can be wound around the outside of the housing 10.

The charging station 2 is configured as a wallbox and mounted on a wall not shown. In particular, the charging station 2 is provided exclusively for wall mounting.

### LIST OF REFERENCE SIGNS

2 charging station
10 housing
12 penetration
20 electronic system
22 control component
24 cooling element
30 temperature control device
32 heat emitting pipe
34 outer section
36 cooling surfaces
38 cooling element
40 fan
50 charging cable
52 charging plug
54 free end
100 wall
U environment
W heat carrier

1. Charging station for charging an electric vehicle, the charging station comprising:
a housing,
an electronic system arranged in the housing for controlling a charging current,
a temperature control device to be connected or connected to the electronic system in a heat-conducting manner for controlling the temperature of the electronic system,
wherein the temperature control device has a heat emitting pipe with a fluid heat carrier, and the heat emitting pipe is guided out of the housing via at least one sealed penetration of the housing.

2. Charging station according to claim 1, wherein:
the heat emitting pipe has a heat pipe with a capillary structure and/or a two-phase thermosiphon without a capillary structure.

3. Charging station according to claim 1, wherein:
the heat carrier comprises water or at least one other substance which can undergo a phase transition between at least two of solid, liquid and gas.

4. Charging station according to claim 1, wherein:
the temperature control device is adapted to dissipate a heat flow emanating from the electronic system of up to or at least 250 W, 500 W or 1000 W at an ambient temperature of up to 60° C.

5. Charging station according to claim 1, wherein:
the heat emitting pipe is connected to a control component of the electronic system in a heat-conducting manner.

6. Charging station according to one of the preceding claims, characterized in that claim 1, wherein:
the heat emitting pipe is soldered, glued, clamped, screwed and/or inserted to the electronic system and/or to the cooling element.

7. Charging station according to claim 1, wherein:
an outer section of the heat emitting pipe is arranged outside the housing for heat exchange with the environment.

8. Charging station according to claim 1, wherein:
the penetration has a sealing device and the heat emitting pipe is guided out of the housing through the sealing device arranged on the housing and/or on the heat emitting pipe.

9. Charging station according to claim 7, wherein:
the outer section has cooling surfaces and/or a cooling element.

10. Charging station according to claim 7 wherein:
the outer section is arranged on the housing in an impact-protected manner, in that the outer section is delimited and/or surrounded at least in sections by the housing and/or is arranged above the housing.

11. Charging station according to claim 1, wherein:
the heat emitting pipe is arranged non-horizontally and/or vertically at least in sections.

12. Charging station according to claim 1, wherein:
the temperature control device has a fan that can be activated depending on the temperature.

13. Charging station according to claim 1, further comprising:
a charging cable which is electrically connected to the electronic system and has a charging plug at a free end of the charging cable for connection to the electric vehicle.

14. Charging station according to claim 1, wherein:
the heat emitting pipe has an elongated metallic vessel in which a volume containing the heat carrier is hermetically encapsulated, wherein the vessel has an evaporator area for absorbing heat by evaporation of the heat carrier in the volume and a condenser area spaced apart from the evaporator area for dissipating heat by condensation of the heat carrier in the volume.

15. Charging station according to claim 1, wherein:
the charging station is configured as a wallbox for wall mounting.

16. Use of a charging station according to claim 1 as a wallbox for wall mounting.

17. Use of a temperature control device with a heat emitting pipe containing a fluid heat carrier in a charging station for charging an electric vehicle, the charging station having a housing, an electronic system arranged in the housing for controlling a charging current, wherein the temperature control device for controlling a temperature of the electronic system is to be connected or is connected to the electronic system in a heat-conducting manner, and wherein the heat emitting pipe is to be guided or is guided out of the housing via at least one penetration of the housing which is to be sealed or is sealed.

18. Charging station according to claim 8, wherein:
the sealing device comprises a cable gland.

19. A charging station comprising:
a housing;
an electronic system configured to control a charging current within said housing;
an electronic system cooling element adjacent to said electronic system;
a heat emitting pipe coupled to said electronic system cooling element, a portion of said heat emitting pipe extending through an opening in said housing and out of said housing;
a condensable heat carrier encapsulated within said heat emitting pipe;
a seal placed within the opening in said housing and around said heat emitting pipe;
a heat emitting pipe cooling surface placed outside of said housing and coupled to said heat emitting pipe on the portion of said heat emitting pipe extending out of said housing.

20. A charging station as recited in claim 19 wherein:
said electronic system cooling element comprises an evaporator, whereby heat is absorbed by evaporation of the condensable heat carrier; and
said heat emitting pipe cooling surface comprises a condenser, whereby heat is released by condensation of the condensable heat carrier.
